(19) United States
(12) Patent Application Publication
(10) Pub. No.: US 2025/0035525 A1
(43) Pub. Date: Jan. 30, 2025

(54) WEAR TEST METHOD AND DEVICE FOR END MILLING CUTTER

(71) Applicants: Zhejiang Xizi Spirit Aviation Industry Co., Ltd., Hangzhou (CN); Hangzhou Dianzi University, Hangzhou (CN)

(72) Inventors: Yun Fu, Hangzhou (CN); Pingfeng Tian, Hangzhou (CN); Zuji Li, Hangzhou (CN); Zhen Zhang, Hangzhou (CN); Jing Ni, Hangzhou (CN)

(73) Assignees: Zhejiang Xizi Spirit Aviation Industry Co., Ltd,, Hangzhou (CN); Hangzhou Dianzi University, Hangzhou (CN)

(21) Appl. No.: 18/772,912

(22) Filed: Jul. 15, 2024

Related U.S. Application Data
(63) Continuation of application No. PCT/CN2024/090497, filed on Apr. 29, 2024.

(30) Foreign Application Priority Data
Jul. 7, 2023 (CN) 202310830122.2

(51) Int. Cl. G01N 3/56; G01N 3/06; G06F 30/17; H04N 23/695

(52) U.S. Cl. CPC G01N 3/56; G01N 3/068; G06F 30/17; G01N 2203/0226; H04N 23/695

(57) ABSTRACT

A wear test method and device for an end milling cutter are provided. The wear test method includes following steps: S10, establishing a single-edge end milling cutter model in a three-dimensional modeling software, and importing the end milling cutter model into a finite element software; S20, analyzing a maximum temperature generated when the end milling cutter is milling, and determining the maximum temperature; S30, heating a tip of the end milling cutter by a point heat source device; S40, performing wear tests on the end milling cutter; S50, repeating the wear tests and recording wear states of the end milling cutter, and test conditions are changed to perform end milling cutter tests and record the wear states of the end milling cutter; and S60: comparing the wear states of end milling cutter obtained under various conditions, and establishing an acceleration model.

### CROSS-REFERENCE TO RELATED APPLICATIONS

This application is a continuation of PCT/CN2024/090497, filed on Apr. 29, 2024, and claims priority of Chinese Patent Application No. 202310830122.2, filed on Jul. 7, 2023, the entire contents of which are incorporated herein by reference.

### TECHNICAL FIELD

The disclosure relates to the technical field of cutter wear detection, and in particular to a wear test method and device for an end milling cutter.

### BACKGROUND

As an essential machining tool for metal milling, end milling cutter are widely used in the field of modem machinery manufacturing. When performing milling operations, the end milling cutter often needs to work continuously for several hours under high-temperature harsh working conditions, which leads to the increased wear of the end milling cutter, fails to meet the accuracy requirements and causes tool failure. In order to solve this problem, the cutter wear of end milling cutter is studied and the wear life curve of cutter is obtained, which may accurately predict the duration of cutter wear and effectively reduce the economic loss caused by cutter wear.

In the prior art, the existing cutter wear test methods generally collect the cutter wear width through intermittent milling workpiece by end milling cutter, which requires hundreds or even thousands of times of collection, consumes a lot of time, and is long in test period and low in test efficiency. In view of the problems in the prior art, it is necessary to design a new wear test scheme and an acceleration device for the end milling cutter, so as to quickly obtain the wear life curve of the cutter and improve the wear test efficiency of the end milling cutter.

### SUMMARY

The present disclosure aims to overcome the problems of long period and low efficiency of end milling cutter wear test, which fails to meet the rapid test requirements, and provides a test method and a test device for accelerating end milling cutter wear at high temperature. According to the disclosure, the maximum temperature is obtained by finite element simulation of the point heat source, and the tip of the end milling cutter is heated to the maximum temperature by the heating device, so that the accuracy of testing the service life of the end milling cutter is improved, and the automation of the end milling wear test is accelerated.

In order to achieve the above objectives, the present disclosure is realized by the following technical scheme.

A wear test method for an end milling cutter is provided, which includes following steps:
S10, establishing a single-edge end milling cutter model in a three-dimensional modeling software, and importing the end milling cutter model into a finite element software;
S20, analyzing a maximum temperature generated when the end milling cutter is milling, and determining the maximum temperature;
S30, heating a tip of the end milling cutter by a point heat source device;
S40, performing wear tests on the end milling cutter;
S50, repeating the wear tests and recording wear states of the end milling cutter, where test conditions are changed to perform end milling cutter tests and record the wear states of the end milling cutter; and
S60, comparing the wear states of end milling cutter obtained under various conditions, and establishing an acceleration model.

Optionally, in the S10, a cutting edge of the end milling cutter is simplified from multi-cutting edges to a single-cutting edge in the single-edge end milling cutter model to mill a workpiece, a milling cycle of the cutter is simplified to a milling cycle of the single-cutting edge, and a wear of the end milling cutter is simplified to a wear of the single-cutting edge.

Optionally, in the S20, the maximum temperature a1 generated when the end milling cutter is milling is analyzed by a formula

$$θ = \frac{{q}_{p}}{{cp ( 4 Π a τ )}^{3 / 2}} {e}^{\frac{{X}^{2} + {y}^{2} + {z}^{2}}{4 a τ}} ;$$

where θ is temperature rise (° C.) at any point in a medium, qₚ is heat (J) emitted by a point heat source at an instant, c is specific heat (J/kg·C) of a heat-conducting medium, p is density (kg/m³) of the heat-conducting medium, a is thermal diffusivity (m²/s), t is any time (s) after the heat source generates heat instantaneously, and coordinates of the point heat source point are an origin of a selected rectangular coordinate system.

Optionally, in the S30, during the tests, the point heat source device on a mechanical arm heats the tip, under a detection by an infrared temperature sensor, a temperature of the tip is enabled to rise to a1, and then the mechanical arm rotates, and the point heat source device does not heat up any more.

Optionally, in the S40, after a milling process, a motor controls a lead screw to rotate, and a high-speed camera on the lead screw moves to photograph a surface of the end milling cutter after milling and record image data, and after finishing recording, the motor controls the lead screw to rotate and the high-speed camera on the lead screw moves away;
when the high-speed camera moves to an original position, the mechanical arm rotates, and the point heat source device heats the tip under a detection of an infrared temperature sensor to the maximum temperature a1, and the mechanical arm rotates and moves the point heat source device away.

Optionally, in the S50, the wear tests on the end milling cutter are repeated until the cutter is worn out and fails, data a1 is recorded, and a wear curve for the end milling cutter is plotted; tests on the end milling cutter are performed without a high temperature condition, data a2 is recorded, and another wear curve for the end milling cutter is plotted.

Optionally, in the S60, the acceleration model is established through wear states of the end milling cutter obtained by comparing the data a1 and the data a2.

A wear test device for an end milling cutter is provided, which includes an infrared temperature sensor, a lead screw, a mechanical arm and a point heat source device arranged on the mechanical arm, where the end milling cutter is provided with a tip, and the point heat source device is used for heating the tip; the infrared temperature sensor is used for detecting a temperature of the tip, and a high-speed camera is arranged on the lead screw, and the high-speed camera is used for photographing a surface of the end milling cutter after milling and recording image data.

Optionally, the wear test device for an end milling cutter further includes a motor for controlling the lead screw to rotate.

Optionally, the wear test device for an end milling cutter further includes a test bench. The mechanical arm and the lead screw are both arranged above the test bench.

According to the disclosure, the way of obtaining the temperature of the tip of the end milling cutter is equivalently simplified based on model established by the heat source method, combining with the actual tests to obtain the maximum temperature suitable for the case of not changing the wear and failure of the cutter, and a high-temperature accelerated experimental platform is built, so that the cutter wear is accelerated by heating the tip at high temperature and the cutter wear life curve is efficiently obtained.

According to the disclosure, the maximum temperature is obtained by finite element simulation of the point heat source, and the tip of the end milling cutter is heated to the maximum temperature by the heating device, so that the accuracy of testing the service life of the end milling cutter is improved, and the automation of end milling cutter wear is accelerated.

### BRIEF DESCRIPTION OF THE DRAWINGS

In order to explain the embodiments of the present disclosure or the technical scheme in the prior art more clearly, the drawings used in the description of the embodiments or the prior art will be briefly introduced below. Apparently, the drawings in the following description are only some embodiments of the present disclosure, and other drawings may be obtained according to the structures shown in these drawings without creative effort for those of ordinary skill the art.

FIG. 1 is a schematic structural diagram of an embodiment of the present disclosure,

FIG. 2 is a schematic diagram of a Polycrystalline Diamond (PCD) end milling cutter according to an embodiment of the present disclosure,

FIG. 3 is a diagram of a point heat source device according to an embodiment of the present disclosure,

FIG. 4 is a heating diagram of a tip of the end milling cutter according to an embodiment of the present disclosure, and

FIG. 5 is a flow diagram of a wear test method according to an embodiment of the present disclosure.

### DETAILED DESCRIPTION OF THE EMBODIMENTS

Hereinafter, embodiments of the present disclosure will be described in detail, examples of which are illustrated in the accompanying drawings. The embodiments described below by referring to the drawings are exemplary and are intended to explain the disclosure, but should not be construed as limiting the disclosure.

In the description of the present disclosure, it should be noted that the orientation or position relationships indicated by the terms, such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer” are based on the orientation or position relationships shown in the drawings, which are only for the convenience of describing and simplifying the present disclosure, rather than indicating or implying that the device or elements must be in designated orientation, or configured or operated in designated orientation and should not be construed as a limitation of this disclosure.

In addition, the terms “first” and “second” are only used for descriptive purposes, and should not be understood as indicating or implying relative importance or implicitly indicating the number of indicated technical features. Therefore, the features defined as “first” and “second” should explicitly or implicitly include at least one of these features. In the description of the present disclosure, “multiple” means at least two, such as two, three, etc., unless otherwise specifically defined.

In the present disclosure, unless otherwise specified and limited, the terms “install”, “connection”, “connect” and “fix” should be broadly understood. For example, these terms may refer to fixed connection, detachable connection or integration; may refer to mechanical connection, electrical connection or in communication with each other; may refer to direct connection or indirect connection through an intermediary, may also refer to internal communication or interaction between two elements, unless otherwise specified. For those skilled in the art, specific meanings of the above terms in the present disclosure may be understood according to specific situations.

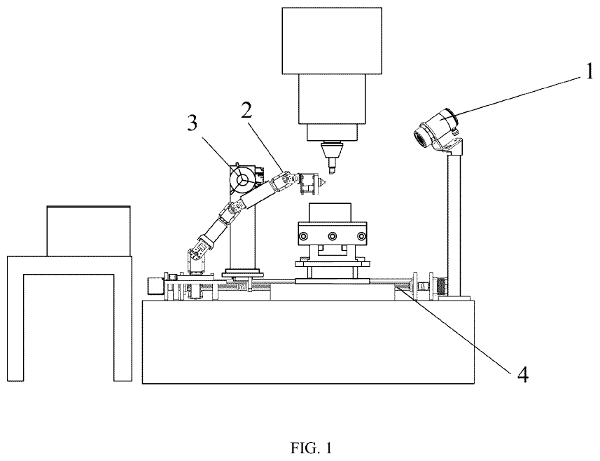

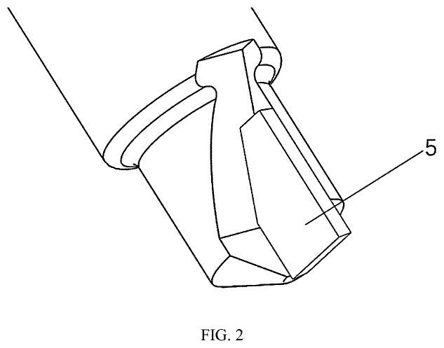

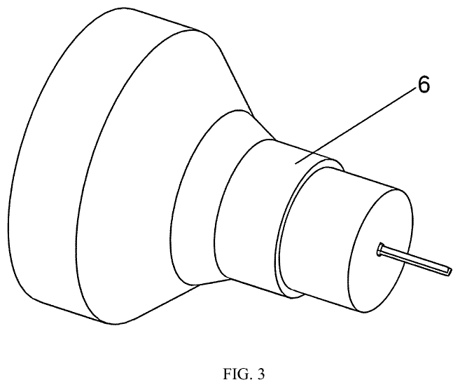

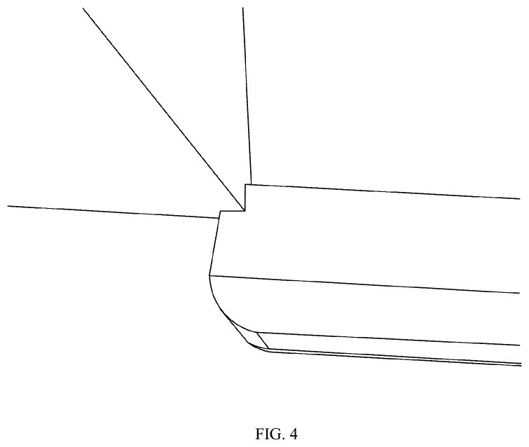

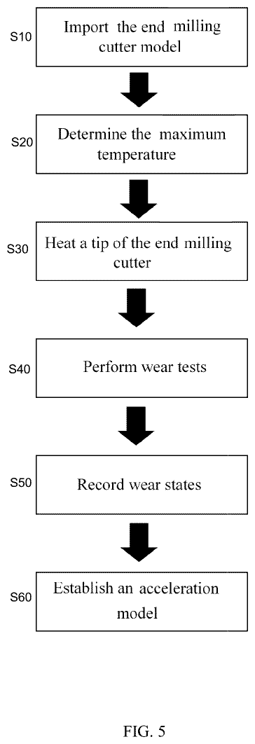

With reference to FIG. 1-FIG. 5, a wear test method for an end milling cutter in an embodiment of the present disclosure includes following steps:
S10, a single-edge end milling cutter model is established in a three-dimensional modeling software, and the end milling cutter model is imported into a finite element software;
S20, a maximum temperature generated when the end milling cutter is milling is analyzed, and the maximum temperature is determined;
S30, a tip of the end milling cutter is heated by a point heat source device;
S40, wear tests on the end milling cutter are performed;
S50, the wear tests are repeated and wear states of the end milling cutter are recorded, and test conditions are changed to perform end milling cutter tests and record the wear states of the end milling cutter; and
S60, the wear states of end milling cutter obtained under various conditions are compared, and an acceleration model is established.

In the embodiment, in the S10, a cutting edge of the end milling cutter is simplified from multi-cutting edges to a single-cutting edge in the single-edge end milling cutter model to mill a workpiece, a milling cycle of the cutter is simplified to a milling cycle of the single-cutting edge, and a wear of the end milling cutter is simplified to a wear of the single-cutting edge.

In the embodiment, in the S20, the maximum temperature a1 generated when the end milling cutter is milling is analyzed by a formula

$$θ = \frac{{q}_{p}}{{cp ( 4 Π a τ )}^{3 / 2}} {e}^{\frac{{X}^{2} + {y}^{2} + {z}^{2}}{4 a τ}} ;$$

where θ is temperature rise (° C.) at any point in a medium, qₚ is heat (J) emitted by a point heat source at an instant, c is specific heat (J/kg·C) of a heat-conducting medium, p is density (kg/m³) of the heat-conducting medium, a is thermal diffusivity (m²/s), t is any time (s) after the heat source generates heat instantaneously, and coordinates of the point heat source are an origin of a selected rectangular coordinate system.

In the embodiment, in the S30, during the tests, the point heat source device on a mechanical arm heats the tip, under a detection by an infrared temperature sensor, a temperature of the tip is enabled to rise to a1, and the mechanical arm rotates, and the point heat source device does not heat up any more.

In the embodiment, in the S40, after a milling process, a motor controls a lead screw to rotate, and a high-speed camera on the lead screw moves to photograph a surface of the end milling cutter after milling and record image data, and after finishing recording, the motor controls the lead screw to rotate and the high-speed camera on the lead screw moves away.

When the high-speed camera moves to an original position, the mechanical arm rotates, and the point heat source device heats the tip under the detection of the infrared temperature sensor to the maximum temperature a1, and the mechanical arm rotates and moves the point heat source device away.

In the embodiment, in the S50, the wear tests on the end milling cutter are repeated until the cutter is worn out and fails, data a1 is recorded, and a wear curve for the end milling cutter is plotted; tests on the end milling cutter are carried out without a high temperature condition, data a2 is recorded, and another wear curve for the end milling cutter is plotted.

In the embodiment, in the S60, the acceleration model is established through wear states of the end milling cutter obtained by comparing the data a1 and the data a2.

The present disclosure further provides a wear test device for an end milling cutter. The wear test device for an end milling cutter includes the infrared temperature sensor 1, the lead screw 4, the mechanical arm 2 and the point heat source device 6 arranged on the mechanical arm 2. The end milling cutter is provided with the tip 5, and the point heat source device 6 is used for heating the tip 5. The infrared temperature sensor 1 is used for detecting the temperature of the tip 5. The high-speed camera 3 is arranged on the lead screw 4, and the high-speed camera 3 is used for photographing the surface of the end milling cutter after milling and recording image data.

In the embodiment, the wear test device for an end milling cutter further includes the motor for controlling the lead screw 4 to rotate.

In the embodiment, the wear test device for an end milling cutter further includes a test bench. The mechanical arm 2 and the lead screw 4 are both arranged above the test bench.

In the embodiment, PCD end milling cutter has the working spindle speed of 800 r/min, the feed speed of 80 mm/min, the cutting width of 2 mm and the cutting depth of 3 mm. The workpiece material is 100×100×180 mm structural steel. The specific implementation steps are as follows.

The cutting edge of the end milling cutter is simplified from multiple cutting edges to a single cutting edge to mill a workpiece, the milling cycle of the cutter is simplified to a milling cycle of the single cutting edge, and a wear of the end milling cutter is simplified to a wear of the single cutting edge; a single-edge end milling cutter model is established in a three-dimensional modeling software, and the end milling cutter model is imported into the finite element software; the maximum temperature generated when the end milling cutter is milling is analyzed.

During the tests, the point heat source device 6 on the mechanical arm 2 heats the tip 5, and under the detection of the infrared temperature sensor 1, the temperature of the tip 5 rises to a1. Then the mechanical arm 2 rotates, and the point heat source device 6 no longer heats up, and milling is started at this time.

After a 100 mm milling process, the motor controls the lead screw 4 to rotate, and the high-speed camera 3 on the lead screw moves to photograph the surface of the end milling cutter after milling and the image data is recorded through the high-speed camera. After the recording is completed, the motor controls the lead screw 4 to rotate, so as to move the high-speed camera 3 on the lead screw away.

When the high-speed camera moves to the original position, the mechanical arm 2 rotates, and the point heat source device heats the tip 5 under the detection of the infrared temperature sensor to the maximum temperature a1, and the mechanical arm 2 rotates and moves the point heat source device away.

The above steps are repeated until the cutter is worn out and fails, the data a1 is recorded, and the cutter wear curve of the end milling cutter is plotted.

The end milling cutter tests are conducted without the high temperature condition, the data a2 is recorded, and the other wear curve of end milling cutter is plotted.

The data a1 and the data a2 are compared, the acceleration model of cutter wear is established.

According to the disclosure, the way of obtaining the temperature of the tip of the end milling cutter is equivalently simplified based on model established by the heat source method, combining with the actual tests to obtain the maximum temperature suitable for the case of not changing the wear and failure of the cutter, and the high-temperature accelerated experimental platform is built, so that the cutter wear is accelerated by heating the tip at high temperature and the cutter wear life curve is efficiently obtained.

The technical features of the above-mentioned embodiments may be combined arbitrarily. In order to make the description concise, not all possible combinations of the technical features in the above-mentioned embodiments are described. However, as long as there is no contradiction between the combinations of these technical features, they should be considered as the scope recorded in the specification.

The above-mentioned embodiments only express several implementations of the present disclosure, and descriptions are more specific and detailed, but should not be construed as limiting a scope of the disclosure. It should be pointed out that for those of ordinary skill in the art, without departing from the concept of this disclosure, modifications and improvements may be made, which fall within the protection scope of this disclosure. Therefore, the protection scope of the present disclosure shall be subject to the attached claims.

What is claimed is:

1. A wear test method for an end milling cutter, comprising following steps:
S10, establishing a single-edge end milling cutter model in a three-dimensional modeling software, and importing the end milling cutter model into a finite element software;
S20, analyzing a maximum temperature generated when the end milling cutter is milling, and determining the maximum temperature;
S30, heating a tip of the end milling cutter by a point heat source device;
S40, performing wear tests on the end milling cutter;
S50, repeating S30 and S40, and recording wear states of the end milling cutter, wherein test conditions are changed to perform end milling cutter tests and record the wear states of the end milling cutter; and
S60, comparing the wear states of the end milling cutter obtained under various conditions, and establishing an acceleration model.

2. The wear test method for an end milling cutter according to claim 1, wherein in the S10, a cutting edge of the end milling cutter is simplified from multi-cutting edges to a single-cutting edge in the single-edge end milling cutter model to mill a workpiece, a milling cycle of the cutter is simplified to a milling cycle of the single-cutting edge, and a wear of the end milling cutter is simplified to a wear of the single-cutting edge.

3. The wear test method for an end milling cutter according to claim 1, wherein in the S20, the maximum temperature generated when the end milling cutter is milling is analyzed by a formula
$$θ = \frac{{q}_{p}}{{cp ( 4 Π a τ )}^{3 / 2}} {e}^{\frac{{X}^{2} + {y}^{2} + {z}^{2}}{4 a τ}} ;$$
wherein θ is temperature rise (° C.) at any point in a medium, q^{p} is heat (J) emitted by a point heat source at an instant, c is specific heat (J/kg·C) of a heat-conducting medium, p is density (kg/m³) of the heat-conducting medium, a is thermal diffusivity (m²/s), t is any time (s) after the heat source generates heat instantaneously, and coordinates of the point heat source are an origin of a selected rectangular coordinate system.

4. The wear test method for an end milling cutter according to claim 1, wherein in the S30, during the tests, the point heat source device on a mechanical arm heats the tip, under a detection by an infrared temperature sensor, a temperature of the tip is enabled to rise to a first temperature value, and the mechanical arm rotates, and the point heat source device does not heat up any more.

5. The wear test method for an end milling cutter according to claim 1, wherein in the S40, after a milling process, a motor controls a lead screw to rotate, and a high-speed camera on the lead screw moves to photograph a surface of the end milling cutter after milling and record image data, and after finishing recording, the motor controls the lead screw to rotate and the high-speed camera on the lead screw moves away;
when the high-speed camera moves to an original position, a mechanical arm rotates, and the point heat source device heats the tip under a detection of an infrared temperature sensor to the maximum temperature, and the mechanical arm rotates and moves the point heat source device away.

6. The wear test method for an end milling cutter according to claim 1, wherein in the S50, the wear tests on the end milling cutter are repeated until the cutter is worn out and fails, data a1 is recorded, and a wear curve for the end milling cutter is plotted; tests on the end milling cutter are performed without a high temperature condition, data a2 is recorded, and another wear curve for the end milling cutter is plotted.

7. The wear test method for an end milling cutter according to claim 1, wherein in the S60, the acceleration model is established through the wear states of the end milling cutter obtained by comparing data a1 and data a2.

8. A wear test device for an end milling cutter, comprising: an infrared temperature sensor, a lead screw, a mechanical arm and a point heat source device arranged on the mechanical arm, wherein the end milling cutter is provided with a tip, and the point heat source device is used for heating the tip; the infrared temperature sensor is used for detecting a temperature of the tip, and a high-speed camera is arranged on the lead screw, and the high-speed camera is used for photographing a surface of the end milling cutter after milling and recording image data.

9. The wear test device for an end milling cutter according to claim 8, further comprising a motor for controlling the lead screw to rotate.

10. The wear test device for an end milling cutter according to claim 8, further comprising a test bench, wherein the mechanical arm and the lead screw are both arranged above the test bench.

11. The wear test device for an end milling cutter according to claim 9, further comprising a test bench, wherein the mechanical arm and the lead screw are both arranged above the test bench.
